(19) United States
(12) Patent Application Publication
(10) Pub. No.: US 2024/0030216 A1
(43) Pub. Date: Jan. 25, 2024

(54) SEMICONDUCTOR DEVICE

(71) Applicant: Nuvoton Technology Corporation, Hsinchu (TW)

(72) Inventor: Wen-Ying Wen, Hsinchu (TW)

(73) Assignee: Nuvoton Technology Corporation, Hsinchu (TW)

(21) Appl. No.: 17/938,953

(22) Filed: Sep. 7, 2022

(30) Foreign Application Priority Data
Jul. 25, 2022 (TW) 111127823

(51) Int. Cl. H01L 27/06; H01L 29/20; H01L 29/205; H01L 29/40; H01L 29/778

(52) U.S. Cl. CPC H01L 27/0605; H01L 29/2003; H01L 29/205; H01L 29/402; H01L 29/7786

(57) ABSTRACT

A semiconductor device includes a metal-insulator-semiconductor high-electron-mobility transistor (MISHEMT) and a Schottky gate HEMT. The Schottky gate HEMT and the MISHEMT are connected in series, and a Schottky gate of the Schottky gate HEMT is electrically connected with the source of the MISHEMT so as to generate a forward diode from the source to the drain of the MISHEMT. The series-connected structure is good for increasing the breakdown voltage of the semiconductor device, and the forward diode can reduce the power loss.

### CROSS-REFERENCE TO RELATED APPLICATION

This application claims the priority benefit of Taiwan application serial no. 111127823, filed on Jul. 25, 2022. The entirety of the above-mentioned patent application is hereby incorporated by reference herein and made a part of this specification.

### BACKGROUND

### Technical Field

The disclosure relates to a high-electron-mobility transistor (HEMT), and in particular, to a semiconductor device combining different HEMTs.

### Description of Related Art

A D-mode metal-insulator-semiconductor high-electron-mobility transistor (MISHEMT) is a currently developed transistor that can be applied to high-voltage power devices. And it generally needs to be used in combination with a low-voltage silicon (LV Si) MOSFET to form a cascode circuit.

However, when the above-mentioned system performs on-to-off switching (on-to-off switch), voltage overshooting occurs between the two components (MISHEMT and LV Si MOSFET) in the cascode circuit. As a result, the drain-to-gate (lower-side element) and gate-to-source (upper-side element) of the two elements are burned out.

### SUMMARY

The present invention provides a semiconductor device, which can prevent the occurrence of voltage overshoot, thereby preventing the lower-side element and the upper-side element in the cascode circuit from being burned out.

The present invention further provides a semiconductor device capable of reducing breakdown voltage and power loss.

A semiconductor device includes a metal-insulator-semiconductor high-electron-mobility transistor (MISHEMT) and a Schottky gate HEMT. The Schottky gate HEMT and the MISHEMT are connected in series, and a Schottky gate of the Schottky gate HEMT is electrically connected with the source of the MISHEMT so as to generate a forward diode from the source to the drain of the MISHEMT.

In an embodiment of the present invention, the MISHEMT includes a D-mode MISHEMT.

In an embodiment of the present invention, the semiconductor device further includes a low voltage silicon field effect transistor (LV Si MOSFET), coupled to the D-mode MISHEMT so as to generate a cascode circuit.

In an embodiment of the present invention, the LV Si MOSFET has a second source, a second gate and a second drain, and the second source is electrically connected to the first gate of the D-mode MISHEMT, and the second drain is electrically connected to the first source of the D-mode MISHEMT.

In an embodiment of the present invention, the structure of the D-mode MISHEMT comprises: a channel layer formed on a substrate, a barrier layer formed on the channel layer, a cap layer formed on the barrier layer, a gate dielectric layer formed on the cap layer, the first gate formed on the gate dielectric layer, and the first source and the first drain. The first source and the first drain are respectively disposed on both sides of the first gate and pass through the gate dielectric layer, the cap layer and the barrier layer to contact the channel layer.

In an embodiment of the present invention, the Schottky gate of the Schottky gate HEMT is disposed on the cap layer between the first gate and the first drain, and the Schottky gate HEMT further comprises a source field plate connecting the Schottky gate and the first source of D-mode MISHEMT.

In an embodiment of the present invention, the channel layer is an undoped gallium nitride layer, the barrier layer is an aluminum gallium nitride layer, and the cap layer is a gallium nitride layer.

In an embodiment of the present invention, the MISHEMT is a normally off MISHEMT.

In an embodiment of the present invention, the structure of the normally off MISHEMT includes: a channel layer formed on a substrate, a barrier layer formed on the channel layer, the first gate formed on the barrier layer, a P-type gallium nitride layer disposed between the barrier layer and the first gate, and the first source and the first drain. The first source and the first drain are respectively disposed on both sides of the first gate and pass through the barrier layer to contact the channel layer.

In an embodiment of the present invention, the Schottky gate of the Schottky gate HEMT is disposed on the barrier layer between the first gate and the first drain, and the Schottky gate HEMT further comprises a source field plate connecting the Schottky gate and the first source of the normally off MISHEMT.

In an embodiment of the present invention, the channel layer is an undoped gallium nitride layer and the barrier layer is an aluminum gallium nitride layer.

In an embodiment of the present invention, the semiconductor device further includes an inner dielectric layer covering the first gate and having an opening exposing the Schottky gate, and the source field plate is formed on the inner dielectric layer and is in direct contact with the Schottky gate through the opening.

Based on the above, in the semiconductor device of the invention, a Schottky gate HEMT is connected in series with the MISHEMT. Therefore, the voltage overshooting phenomenon can be alleviated by the series-connected transistors, thereby increasing the overall breakdown voltage of the semiconductor device. Moreover, when the present invention is applied to the normally-on MISHEMT and the normally-off MISHEMT, the effect of increasing the breakdown voltage can be achieved. In addition, since the Schottky gate of the Schottky gate HEMT is electrically connected to the source of the MISHEMT, a forward diode is formed, thereby reducing the power loss of the semiconductor device of the present invention.

To make the aforementioned more comprehensible, several embodiments accompanied with drawings are described in detail as follows.

### BRIEF DESCRIPTION OF THE DRAWINGS

FIG. 1 is a schematic cross-sectional view of a semiconductor device according to a first embodiment of the present invention.

FIG. 2 is an equivalent circuit diagram of the semiconductor device of FIG. 1.

FIG. 3 is a schematic cross-sectional view of a semiconductor device according to a second embodiment of the present invention.

FIG. 4 is an equivalent circuit diagram of the semiconductor device of FIG. 3.

### DESCRIPTION OF THE EMBODIMENTS

The accompanying drawings in the following embodiments are intended to more completely describe the embodiments of the disclosure, but the disclosure may still be implemented in many different forms and is not limited to the described embodiments. In addition, for the sake of clarity, the relative distance, size, and location of each device or pipeline may be reduced or enlarged.

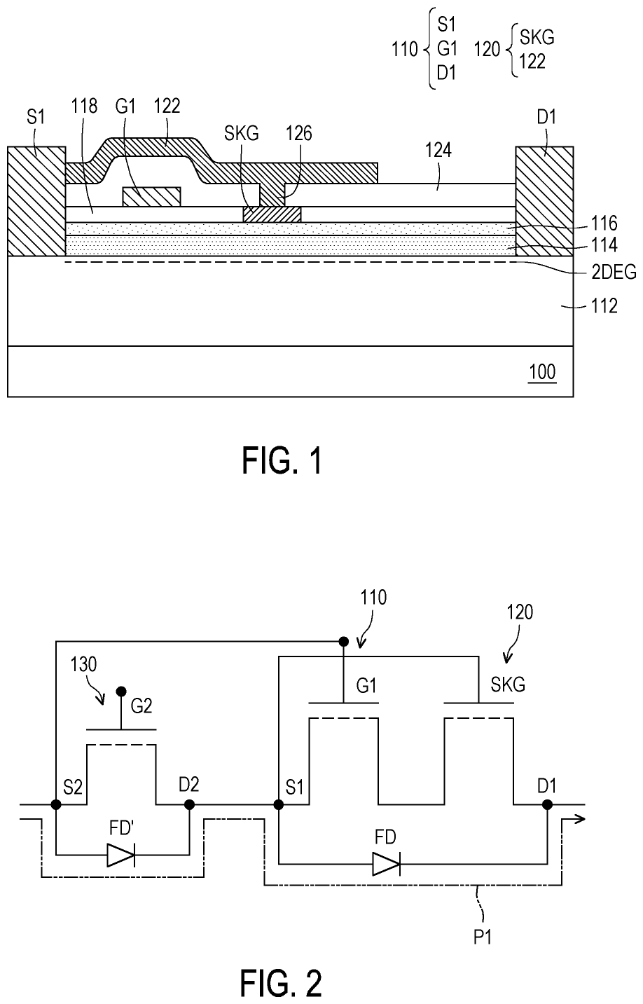

FIG. 1 is a schematic cross-sectional view of a semiconductor device according to a first embodiment of the present invention. FIG. 2 is an equivalent circuit diagram of the semiconductor device of FIG. 1.

Referring to FIG. 2, the semiconductor device of the embodiment includes a D-mode metal-insulator-semiconductor high electron mobility transistor (MISHEMT) 100, a Schottky gate HEMT 120, and a low voltage silicon field effect transistor (LV Si MOSFET) 130. The D-mode MISHEMT 110 has a first source 51, a first gate G1, and a first drain D1. The Schottky gate HEMT 120 is connected in series with the D-mode MISHEMT 110. Therefore, the voltage overshooting phenomenon can be alleviated by the series-connected transistors, thereby increasing the overall breakdown voltage of the semiconductor device. The Schottky gate SKG of the Schottky gate HEMT 120 is electrically connected with the first source S1 of the D-mode MISHEMT 110 so as to generate a forward diode FD from the first source S1 to the first drain D1. The LV Si MOSFET 130 is coupled to the D-mode MISHEMT 110 so as to generate a cascode circuit.

From structural point of view, referring to FIG. 1, the structure of the D-mode MISHEMT 110 includes a channel layer 112 formed on a substrate 100, a barrier layer 114 formed on the channel layer 112, a cap layer 116 formed on the barrier layer 114, a gate dielectric layer 118 formed on the cap layer 116, the first gate G1 formed on the gate dielectric layer 118, and the first source S1 and the first drain D1. The first source S1 and the first drain D1 are respectively disposed on both sides of the first gate G1 and pass through the gate dielectric layer 118, the cap layer 116 and the barrier layer 114 to contact the channel layer 112. The channel layer 112 may be formed of undoped gallium nitride (GaN). The material of the barrier layer 114 is an undoped III-V group semiconductor material, such as but not limited to aluminum gallium nitride (AlGaN) or other suitable III-V group materials. The channel layer 112 and the barrier layer 114 are hetero-materials. Therefore, a hetero-interface is formed between the channel layer 112 and the barrier layer 114, and a two-dimensional electron gas (2DEG) can be formed on the hetero-interface due to the band gap of the hetero-materials. In an embodiment, the channel layer 112 is an undoped gallium nitride layer, the barrier layer 114 is an aluminum gallium nitride layer, and the cap layer 116 is a gallium nitride layer. Each layer of the channel layer 112, the barrier layer 114, and the cap layer 116 in the D-mode MISHEMT 110 can use an epitaxial process to form an epitaxial structure. Among them, the epitaxial process is such as metal organic chemical vapor deposition (MOCVD), hydride vapor phase epitaxy (HYPE), molecular beam epitaxy (MBE) or a combination of the aforementioned methods. The gate dielectric layer 118 may be a high-k insulating dielectric material, such as Al₂O₃, HfO₂, Ta₂O₅, Si₃N₄ or a combination thereof.

Continue to refer to FIG. 1, the Schottky gate SKG of the Schottky gate HEMT 120 may be disposed on the cap layer 116 between the first gate G1 and the first drain D1. The forming method is, for example, forming a trench in the gate dielectric layer 118 to expose the underlying cap layer 116, and then depositing the Schottky gate SKG therein. The Schottky gate SKG is a metal gate, and its materials include but are not limited to: a multi-layer of metal combinations with high work function (such as TiN and Ni). As for the way in which the Schottky gate SKG is electrically connected to the first source S1 of the D-mode MISHEMT 110, the connection can be made through a source field plate 122. In an embodiment, the source field plate 122 can be formed by forming an inner dielectric layer 124 to cover the first gate G1 and other structures first. Then, after the first source S1 and the first drain D1 are formed, an opening 126 exposing the Schottky gate electrode SKG is formed in the inner dielectric layer 124. Then, the source field plate 122 is formed on the inner dielectric layer 124, and is in direct contact with the Schottky gate SKG through the above-mentioned opening 126. In another embodiment, the source field plate 122 may be formed by forming the inner dielectric layer 124 first. And after forming the opening 126 exposing the Schottky gate SKG, the opening 126 is filled with conductor material. After it is planarized, the source field plate 122 is deposited on the inner dielectric layer 124. It is electrically connected to the Schottky gate SKG through the conductor material in the opening 126.

In FIG. 2, the LV Si MOSFET 130 has a second source S2, a second gate G2, and a second drain D2. Wherein the second source S2 is electrically connected to the first gate G1 of the D-mode MISHEMT 110, and the second drain D2 is electrically connected to the first source S1 of the D-mode MISHEMT 110, so as to form a so-called cascode circuit. Since the current path P1 may be from the second source S2 of the LV Si MOSFET 130 to the second drain D2 via the forward diode FD', then from the first source S1 of the D-mode MISHEMT 110 to the first drain D1 through the forward diode FD. Therefore, there is no need to pass through multiple epitaxial layers (e.g., the channel layer 112 and the barrier layer 114), so the power loss can be greatly reduced.

In the embodiment, if the substrate 100 is a silicon substrate, the LV Si MOSFET 130 can be directly formed on the substrate 100. In another embodiment, if a silicon layer (not shown) is epitaxially grown on the substrate 100, the LV Si MOSFET 130 can also be formed on the silicon layer. In yet another embodiment, the LV Si MOSFET 130 can be formed on other substrates, and then electrically connected to the D-mode MISHEMT 110 of FIG. 2 through a packaging process.

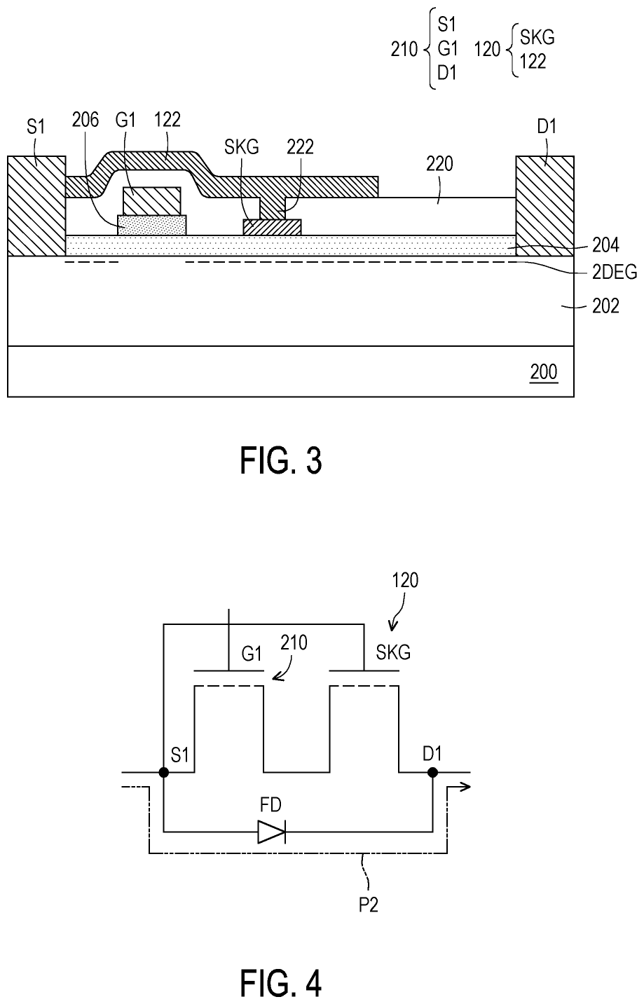

FIG. 3 is a schematic cross-sectional view of a semiconductor device according to a second embodiment of the present invention, wherein the same element symbols as in the first embodiment are used to represent the same or similar parts and components, and the related content of the same or similar parts and components can also refer to the content of the first embodiment, which will not be repeated herein.

Referring to FIG. 3, the semiconductor device of the embodiment includes a normally off MISHEMT 210 and a Schottky gate HEMT 120. The normally off MISHEMT 210 has a first source S1, a first gate G1, and a first drain D1. The Schottky gate HEMT 120 is connected in series with the normally off MISHEMT 210. And the Schottky gate SKG of the Schottky gate HEMT 120 is electrically connected with the first source S1 of the normally off MISHEMT 210 so as to generate a forward diode FD from the first source S1 to the first drain D1.

FIG. 4 is an equivalent circuit diagram of the semiconductor device of FIG. 3.

In FIG. 4, the normally-off MISHEMT 210 and the Schottky gate HEMT 120 connected in series can alleviate the voltage overshoot phenomenon, thereby increasing the overall breakdown voltage of the semiconductor device. Moreover, a current is supplied from the first source S1 to the forward diode FD of the first drain D1, and its current path P2 is from the first source S1 of the normally-off MISHEMT 210 to the first drain D1. Since there is no need to pass through multiple epitaxial layers (such as the P-type gallium nitride layer 206 and the channel layer 202), the power loss of the device can be reduced.

From structural point of view, referring to FIG. 3, the structure of the normally-off MISHEMT 210 includes a channel layer 202 formed on a substrate 200, a barrier layer 204 formed on the channel layer 202, a first gate G1 formed on the barrier layer 204, a P-type gallium nitride layer 206 disposed between the barrier layer 204 and the first gate G1, and the first source S1 and the first drain D1. The first source S1 and the first drain D1 are respectively disposed on both sides of the first gate G1 and pass through the barrier layer 204 to contact the channel layer 202. The channel layer 202 may be formed of undoped GaN. The material of the barrier layer 204 is an undoped III-V group semiconductor material, such as but not limited to AlGaN or other suitable III-V group materials. The channel layer 202 and the barrier layer 204 are hetero-materials. Therefore, a hetero-interface is formed between the channel layer 202 and the barrier layer 204, and a 2DEG can be formed on the hetero-interface due to the band gap of the hetero-materials. The positively charged P-type GaN layer 206 is formed on the barrier layer 204, so the positive charge in the P-type GaN layer 206 will deplete the electrons in the 2DEG to form an enhancement mode (E-mode) structure. Each layer of the channel layer 202, the barrier layer 204, and the P-type gallium nitride layer 206 in the normally-off MISHEMT 210 can use an epitaxial process to form an epitaxial structure. Among them, the epitaxial process is such as MOCVD, HYPE, MBE or a combination of the aforementioned methods.

Continue to refer to FIG. 4, the Schottky gate SKG of the Schottky gate HEMT 120 may be disposed on the barrier layer 204 between the first gate G1 and the first drain D1. The forming method is, for example, forming a trench in the inner dielectric layer to expose the underlying barrier layer 204, and then depositing the Schottky gate SKG therein. Alternatively, it is formed directly on the barrier layer 204 through deposition and etching processes. The Schottky gate SKG is electrically connected to the first source S1 of the normally-off MISHEMT 210 through a source field plate 122. In an embodiment, the source field plate 122 can be formed by forming an inner dielectric layer 220 to cover the first gate G1 and other structures first. Then, after the first source S1 and the first drain D1 are formed, an opening 222 exposing the Schottky gate electrode SKG is formed in the inner dielectric layer 220. Then, the source field plate 122 is formed on the inner dielectric layer 220, and is in direct contact with the Schottky gate SKG through the above-mentioned opening 222. In another embodiment, the source field plate 122 may be formed by forming the inner dielectric layer 220 first. And after forming the opening 222 exposing the Schottky gate SKG, the opening 222 is filled with conductor material. After it is planarized, the source field plate 122 is deposited on the inner dielectric layer 220. It is electrically connected to the Schottky gate SKG through the conductor material in the opening 222.

To sum up, the present invention alleviates the phenomenon of voltage overshooting by connecting a Schottky gate HEMT in series with the MISHEMT. Thereby, the breakdown voltage of the semiconductor device as a whole is increased. Moreover, the Schottky gate of the Schottky gate HEMT is electrically connected to the source of the MISHEMT to form a forward diode. Therefore, when Vgs is off, the current may flow from source to drain through the forward diode, so power loss can be reduced.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A semiconductor device, comprising:
a metal-insulator-semiconductor high-electron-mobility transistor (MISHEMT), having a first source, a first gate, and a first drain; and
a Schottky gate HEMT, connected in series with the MISHEMT, and a Schottky gate of the Schottky gate HEMT is electrically connected with the first source of the MISHEMT so as to generate a forward diode from the first source to the first drain of the MISHEMT.

2. The semiconductor device according to claim 1, wherein the MISHEMT is a D-mode MISHEMT.

3. The semiconductor device according to claim 2, further comprises a low voltage silicon field effect transistor (LV Si MOSFET), coupled to the D-mode MISHEMT so as to generate a cascode circuit.

4. The semiconductor device according to claim 2, wherein the LV Si MOSFET has a second source, a second gate and a second drain, and the second source is electrically connected to the first gate, and the second drain is electrically connected to the first source.

5. The semiconductor device according to claim 2, wherein the structure of the D-mode MISHEMT comprises:
a channel layer, formed on a substrate;
a barrier layer, formed on the channel layer;
a cap layer, formed on the barrier layer;
a gate dielectric layer, formed on the cap layer;
the first gate is formed on the gate dielectric layer; and
the first source and the first drain are respectively disposed on both sides of the first gate and pass through the gate dielectric layer, the cap layer and the barrier layer to contact the channel layer.

6. The semiconductor device according to claim 5, wherein the Schottky gate of the Schottky gate HEMT is disposed on the cap layer between the first gate and the first drain, and the Schottky gate HEMT further comprises a source field plate connecting the Schottky gate and the first source of D-mode MISHEMT.

7. The semiconductor device according to claim 6, further comprises an inner dielectric layer covering the first gate and having an opening exposing the Schottky gate, and the source field plate is formed on the inner dielectric layer and is in direct contact with the Schottky gate through the opening.

8. The semiconductor device according to claim 5, wherein the channel layer is an undoped gallium nitride layer, the barrier layer is an aluminum gallium nitride layer, and the cap layer is a gallium nitride layer.

9. The semiconductor device according to claim 1, wherein the MISHEMT is a normally off MISHEMT.

10. The semiconductor device according to claim 9, wherein the structure of the normally off MISHEMT comprises:
a channel layer, formed on a substrate;
a barrier layer, formed on the channel layer;
the first gate is formed on the barrier layer;
a P-type gallium nitride layer, disposed between the barrier layer and the first gate; and
the first source and the first drain are respectively disposed on both sides of the first gate and pass through the barrier layer to contact the channel layer.

11. The semiconductor device according to claim 10, wherein the Schottky gate of the Schottky gate HEMT is disposed on the barrier layer between the first gate and the first drain, and the Schottky gate HEMT further comprises a source field plate connecting the Schottky gate and the first source of the normally off MISHEMT.

12. The semiconductor device according to claim 11, further comprises an inner dielectric layer covering the first gate and having an opening exposing the Schottky gate, and the source field plate is formed on the inner dielectric layer and is in direct contact with the Schottky gate through the opening.

13. The semiconductor device according to claim 10, wherein the channel layer is an undoped gallium nitride layer and the barrier layer is an aluminum gallium nitride layer.
